(19) United States
(12) Patent Application Publication
(10) Pub. No.: US 2020/0379336 A1
(43) Pub. Date: Dec. 3, 2020

(54) Wave-Front Aberration Metrology of Extreme Ultraviolet Mask Inspection Systems

(71) Applicant: KLA Corporation, Milpitas, CA (US)

(72) Inventors: Dmitriy Zusin, Milpitas, CA (US); Rui-fang Shi, Cupertino, CA (US); Qiang Y. Zhang, Fremont, CA (US)

(21) Appl. No.: 16/864,972

(22) Filed: May 1, 2020

Related U.S. Application Data
(60) Provisional application No. 62/856,719, filed on Jun. 3, 2019.

(51) Int. Cl. G03F 1/24; G03F 1/84; G03F 1/54; G03F 1/60; G03F 1/46; G21K 1/06; G03F 7/20

(52) U.S. Cl. CPC G03F 1/24; G03F 1/84; G03F 1/54; G03F 7/702; G03F 1/46; G21K 1/062; G03F 1/60

(57) ABSTRACT

A metrology system for measuring wave-front aberration of an extreme ultraviolet (EUV) mask inspection system is disclosed. The test mask includes a substrate formed from a material having substantially no reflectivity for EUV illumination, and one or more patterns formed on the substrate, the one or more patterns having a reflective portion configured to reflect EUV illumination, positioned in a common plane with an absorption portion having substantially no reflectivity for EUV illumination, on or above the substrate.

### CROSS-REFERENCE TO RELATED APPLICATION

The present application claims the benefit under 35 U.S.C. § 119(e) of U.S. Provisional Application Ser. No. 62/856,719, filed Jun. 3, 2019, entitled WAVEFRONT ABERRATION METROLOGY FOR EUV MASK INSPECTION SYSTEMS, naming Dmitriy Zusin, Rui-fang Shi, and Qiang Zhang as inventors, which is incorporated herein by reference in the entirety.

### TECHNICAL FIELD

The present disclosure is related generally to wave-front aberration metrology and, more particularly, to wave-front aberration metrology through the use of extreme ultraviolet (EUV) mask inspection systems incorporating test masks.

### BACKGROUND

Generally, nanocircuits and their components have become increasingly sensitive to defects. These defects can compromise the operation of the nanocircuitry or adversely affect the yield of the nanocircuitry. The detection of defects on nanocircuitry is typically performed using an EUV inspection system which illuminates a photomask containing patterns of the manufactured nanocircuit. However, EUV inspection systems rely on an array of optical instruments that frequently distort the images through wave-front aberrations that may corrupt the image of the photomask, precluding the detection of defects.

Existing methods of measuring and mitigating the wave-front aberration introduced by the optical instruments of EUV inspection systems rely on diagnostic test masks. However, existing diagnostic test masks are prone to failure and undesirable performance as a result of the manner in which they are manufactured. For example, existing diagnostic patterns of test masks may introduce shadowing or other undesirable reflective effects to the images. Additionally, existing diagnostic test patterns suffer from a short lifetime as a result of oxidation.

Further, existing methods of measuring and mitigating the wave-front aberration introduced by the optical instruments of EUV inspection systems include identification of aberration using systems and procedures separate from the EUV inspection systems. These methods do not permit quantification and mitigation of wave-front aberrations within the EUV inspections systems themselves, thereby decreasing metrological efficiency.

It is therefore desirable to provide an improved system for the in-situ measurement of wave-front aberration of EUV mask inspection systems.

### SUMMARY

A test mask for measuring wave-front aberration of an EUV mask inspection system is disclosed, in accordance with one or more embodiments of the present disclosure. In one embodiment, the test mask includes a substrate formed from a material having substantially no reflectivity for EUV illumination. In another embodiment, the test mask includes one or more patterns formed on the substrate, wherein the one or more patterns comprise an absorption portion configured to absorb EUV illumination and a reflective portion configured to reflect EUV illumination, wherein the reflective portion and the absorption portion are positioned within a common plane on or above the substrate.

An EUV mask inspection system is disclosed, in accordance with one or more embodiments of the present disclosure. In one embodiment, the system includes an EUV illumination source. In another embodiment, the system includes one or more EUV illumination optics configured to direct an EUV beam from the EUV illumination source onto a test mask, the test mask comprising a substrate formed from a material having substantially no reflectivity for EUV illumination, one or more test masks formed on the substrate, wherein the one or more patterns comprise an absorption portion configured to absorb EUV illumination and a reflective portion configured to reflect EUV illumination, wherein the absorption portion and the reflective portion are positioned within a common plane above the substrate, and one or more caps disposed on at least one of the absorption portion or the reflective portion, the one or more caps being formed from a material suitable to reduce oxidation of one or more portions of the test mask. In another embodiment, the system includes one or more detectors. In another embodiment, the system includes one or more EUV projection optics configured to collect EUV illumination reflected from the test mask and direct the EUV illumination onto the one or more detectors. In another embodiment, the system includes one or more controllers having one or more processors communicatively coupled to the one or more detectors, wherein the one or more processors are configured to executed a set of program instructions maintained in memory, and wherein the set of program instructions are configured to cause the one or more processors to receive one or more signals from the one or more detectors indicative of the EUV illumination reflective from the test mask, and identify one or more wave-front aberrations across the EUV beam based on the one or more signals from the one or more detectors indicative of the EUV illumination received from the test mask.

A method of using an EUV mask inspection system is disclosed, in accordance with one or more embodiments of the present disclosure. In one embodiment, the method includes illuminating a test mask, the test mask comprising a substrate formed from a material having substantially no reflectivity for EUV illumination, one or more patterns formed on the substrate, wherein the one or more patterns comprise an absorption portion configured to absorb EUV illumination and a reflective portion configured to reflect EUV illumination, wherein the absorption portion and the reflective portion are positioned within a common plane above the substrate, and one or more caps disposed on at least one of the absorption portion or the reflective portion, the one or more caps being formed from a material suitable to reduce oxidation of one or more portions of the test mask. In another embodiment, the method includes detecting a reflected beam. In another embodiment, the method includes generating one or more images based on the reflected beam. In another embodiment, the method includes identifying one or more wave-front aberrations across the one or more images. In another embodiment, the method includes providing one or more adjustments for adjusting one or more components of the EUV mask inspection system.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures in which:

FIGS. 1A-1E illustrate cross-section views of a pattern of a test mask for measuring wave-front aberration of an EUV mask inspection system, in accordance with one or more embodiments of the present disclosure.

FIG. 2 illustrates a simplified block diagram view of an EUV mask inspection system, in accordance with one or more embodiments of the present disclosure.

FIG. 3 is a plot illustrating the relationship between the reflectivity of one or more portions of a test mask for measuring wave-front aberrations of an EUV mask inspection system and the angle of an incident beam of light directed at the test mask, in accordance with one or more embodiments of the present disclosure.

FIGS. 4A-4H are plots illustrating the intensity contrast in the imaging pupil for various embodiments of a pattern of a test mask for measuring wave-front aberration of an EUV mask inspection system, in accordance with one or more embodiments of the present disclosure.

FIG. 5 is a process flow diagram illustrating a method for identifying wave-front aberrations in an EUV inspection system via a test mask, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods for wave-front aberration metrology using EUV mask inspection systems incorporating one or more test masks configured to improve the performance of such inspection systems.

EUV mask inspection typically involves the detection of one or more defects of an EUV photomask through the use of EUV illumination (e.g., radiation having an EUV wavelength, such as 13.5 nm). Defects of an EUV photomask may include one or more undesirable deviations that may impact yield and performance of a chip printed with the photomask. EUV inspection systems typically implement one or more reflective elements (e.g., mirrors) to form, based on one or more EUV incident beams directed from the EUV photomask, an image of the EUV photomask. The one or more reflective elements of the EUV inspection system may introduce aberrations to the wave-front at an imaging pupil. Those aberrations may impair or compromise the imaging and inspection of the EUV photomask.

The test mask comprised of pattern 100 may be configured as a diagnostic photomask for measuring the wave-front aberration in an EUV mask inspection system. For example, the test mask may be used in EUV mask inspection systems implemented in the inspection of EUV photomasks. The test mask may include a pattern 100, which pattern 100 may be configured to carry out the functions disclosed herein. The test mask may be configured to reflect EUV illumination so as to substantially and uniformly fill the imaging pupil of the optical system. Based upon the uniformity and intensity of the fill of the imaging pupil, the EUV mask inspection system may measure one or more wave-front aberrations of the system, and determine one or more adjustments to one or more components of the system. Systems and methods for measurement of one or more wave-front aberrations of an EUV mask inspection system are generally described in U.S. Pat. No. 9,335,206, titled “WAVE FRONT ABERRATION METROLOGY OF OPTICS OF EUV MASK INSPECTION SYSTEM” and issued on May 10, 2016, which is incorporated herein by reference in the entirety.

Upon illumination of the test mask with EUV radiation, the test mask may be configured to reflect EUV radiation from a reflective portion of the test mask, and to absorb EUV radiation at an absorption portion of the test mask. For example, the reflective portion may reflect EUV radiation toward an imaging pupil of an EUV mask inspection system, and the absorption portion may absorb EUV light. The EUV mask inspection system may be configured to generate an image of the test mask based on the reflected EUV light and the absence of reflected EUV light that may correspond to the absorption portion of the test mask. In this regard, the test mask is configured such that a high contrast exists between the reflective portion and the absorption portion, where such contrast may be detected by an EUV mask inspection system.

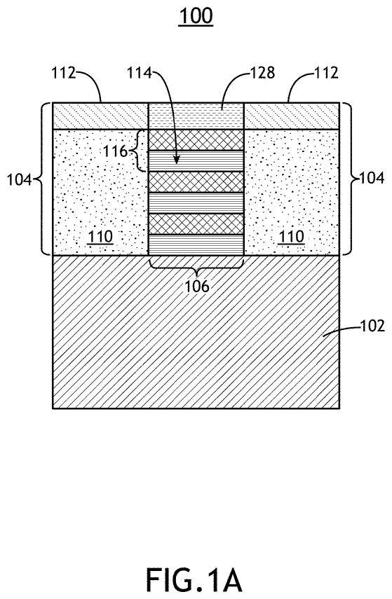

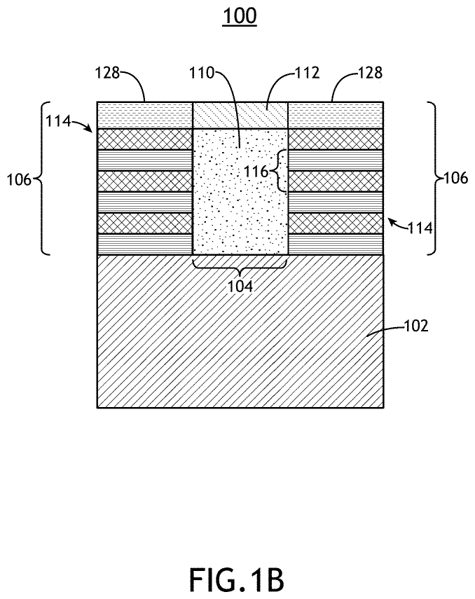

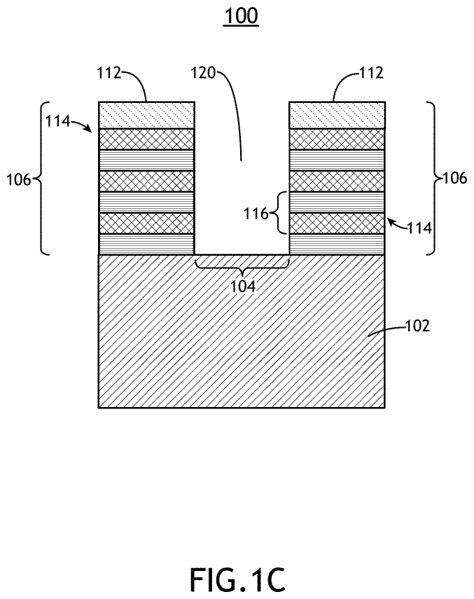

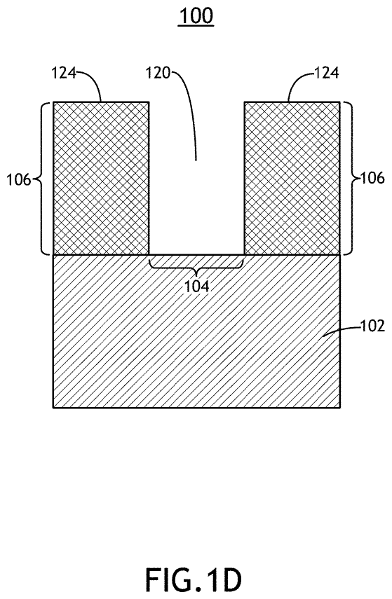

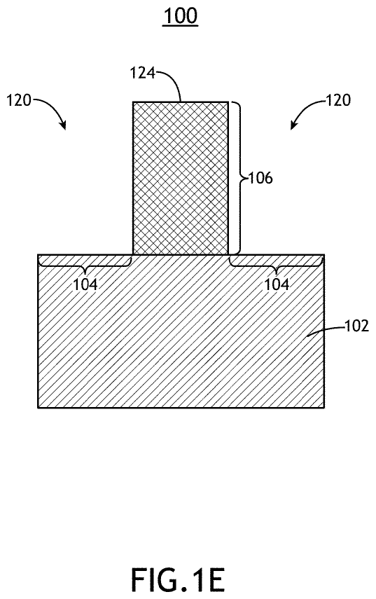

FIGS. 1A through 1E illustrate cross-section views of a pattern 100 of a test mask for measuring wave-front aberration of an EUV mask inspection system, in accordance with one or more embodiments of the present disclosure. The test mask, though not shown in its entirety, may include a substrate 102 formed from a material having substantially no reflectivity for EUV illumination. For example, the substrate 102 may be formed from silicon dioxide (SiO₂). The pattern 100 may include an absorption portion 104 and a reflective portion 106 positioned within a common plane on or above the substrate 102. The absorption portion 104 may be configured to absorb EUV illumination. For example, the absorption portion 104 may be formed from one or more materials configured to absorb EUV illumination. The reflective portion 106 may be configured to reflect EUV illumination. For example, the reflective portion 106 may be formed from one or more materials configured to reflect EUV illumination at a metric of approximately 60%-70% or more.

In one embodiment, illustrated by FIG. 1A, the absorption portion 104 may include one or more absorbers 110 configured to absorb EUV illumination. For example, the one or more absorbers 110 may be formed from a material configured to absorb EUV illumination. The one or more absorbers 110 may include an antireflective coating 112 configured to reduce the reflection of an incident EUV beam from the one or more absorbers 110. The antireflective coating 112 may be formed from a material having substantially no reflectivity for EUV illumination. For example, the antireflective coating 112 may be formed substantially from a transition metal nitrido complex compound, such as TaNO. The antireflective coating 112 may be configured such that the height of the one or more absorbers 110, together with the antireflective coating 112, is equivalent to the height of the reflective portion 106. In another embodiment, the absorption portion 104 may include one or more pinholes configured to expose the substrate 102.

In another embodiment, the reflective portion 106 may include one or more multilayer pillars 114 having a plurality of periodically repeating bilayers 116 configured to reflect EUV illumination. For example, the plurality of periodically repeating bilayers 116 may be configured such that the thickness of each of the periodically repeating bilayers 116 and the periodicity of the repetition of the periodically repeating bilayers 116 may be chosen to reflect EUV illumination in a manner that maximizes reflection toward an imaging pupil of an EUV mask inspection system. The thickness of each of the periodically repeating bilayers 116 may be between approximately 7.0 nm and approximately 7.5 nm. The one or more multilayer pillars 114 may include between approximately five and approximately fifteen periodically repeating bilayers 116.

The plurality of periodically repeating bilayers 116 may be formed from alternating layers of one or more materials reflective of EUV illumination, including, without limitation, molybdenum and silicon. The one or more multilayer pillars 114 may include one or more caps 128 formed from any material configured to reduce the potential for oxidation of one or more portions of the multilayer pillar 114 (e.g., from moisture, oxygen exposure, etc.). For example, the one or more caps 128 may be formed from ruthenium. The one or more caps 128 may be configured such that the height of the one or more multilayer pillars 114, together with the one or more caps 128, is equivalent to the height of the one or more absorbers 110.

The one or more multilayer pillars 114 may include one or more Bragg reflectors configured to maximize the reflection of EUV illumination while minimizing the absorption of EUV illumination. The one or more multilayer pillars 114 may facilitate the reflection of EUV illumination via the interfaces between the layers of the periodically repeating bilayers 116. For example, a periodically repeating bilayer 116 may be formed from a single layer of molybdenum disposed with a single layer of silicon. In a specific example, an incident beam of EUV illumination directed to a test mask containing pattern 100 including the periodically repeating bilayer 116 may be reflected based on the indices of refraction of molybdenum and silicon, respectively, where the greater the difference in the indices of refraction of the two single layers may produce greater reflectivity of EUV illumination. The indices of refraction may vary with the thickness and periodicity of the periodically repeating bilayers 116, which may be configured for use in different optical configurations (e.g., use with EUV inspection systems having different imaging pupil parameters, such as numerical aperture).

The pattern 100 may be formed such that the one or more multilayer pillars 114 are disposed within the one or more pinholes of the absorption portion 104. For example, the one or more absorbers 110 may be formed by depositing the material configured to absorb EUV illumination upon the substrate 102, where the depositing upon the substrate may create one or more pinholes in the material that expose the substrate 102, and the one or more multilayer pillars 114 may be embedded within the one or more pinholes. In this regard, the absorption portion 104 may facilitate the reduction in the oxidation of one or more portions of the one or more multilayer pillars 114 by reducing the exposure of the one or more portions of the one or more multilayer pillars 114 to oxidizing agents of an environment. In an alternative embodiment, the pattern 100 may be formed by depositing the one or more multilayer pillars 114 upon the substrate 102, and by then subsequently depositing the absorption portion 104 over the multilayer pillars 114 and removing the excess absorption portion 104 to form one or more absorbers 110, such as through etching.

In another embodiment, illustrated by FIG. 1B, the pattern 100 may be formed such that the one or more absorbers 110 are disposed within an array of the one or more multilayer pillars 114. For example, the one or more multilayer pillars 114 may be deposited upon the substrate 102 in an array, where the one or more absorbers 110 may be interstitially deposited upon the substrate 102 between the one or more multilayer pillars 114. In an alternative embodiment, the pattern 100 may be formed by depositing the one or more multilayer pillars 114 upon the substrate 102, and by then subsequently depositing the absorption portion 104 over the multilayer pillars 114 and removing the excess absorption portion 104 to form one or more absorbers 110, such as through etching.

In another embodiment, illustrated by FIG. 1C, the absorption portion 104 may include one or more pinholes 120 in the reflective portion 106. For example, the one or more pinholes 120 may include one or more openings between the one or more multilayer pillars 114 that are configured to expose the substrate 102. In this regard, the substrate 102 may be configured to absorb EUV illumination.

In another embodiment, illustrated by FIGS. 1D and 1E, the reflective portion 106 may include one or more pillars of reflective material 124. For example, the reflective portion 106 may include one or more pillars of reflective material 124 formed from a material reflective of EUV illumination, including, without limitation, palladium, platinum, and silver. The pillars of reflective material 124 may be formed from a material having a reflectivity for EUV radiation of approximately 0.5% or more. The reflective material 124 may be formed from a material the reflectivity of which allows the radiation reflected by the reflective material to have a high contrast relative to the absorption portion 104. The pillars of reflective material 124 may be of a thickness that may vary with the desired amount of reflectivity. In a specific example, the thickness of the pillars of reflective material 124 may exceed 100 nm. The absorption portion 104 may comprise one or more pinholes 120 in the reflective portion, where the pinholes 120 are configured to expose the substrate 102.

Although the embodiments described in the present disclosure are described as pillar structures and pinholes, it is noted that other shapes are contemplated. For example, the one or more multilayer pillars 114 may include any shape suitable for the purposes contemplated hereby, including, without limitation, cubes, ovals, and the like. Similarly, the pinholes 120 may be a hole of any shape, including, without limitation, square, oval, and the like.

In one embodiment, the reflective portion 104 is comprised of a single component (e.g., a single multilayer pillar 114 or a single pillar of reflective material 122). In other embodiments, the reflective portion 104 is comprised of multiple components (e.g., a plurality of multilayer pillars 114 or a plurality of pillars of reflective material 122).

In another embodiment, the absorption portion 106 is comprised of a single component (e.g., a single absorber 110 or a single pinhole 120). In other embodiments, the absorption portion 106 is comprised of multiple components (e.g., a plurality of absorbers 110 or a plurality of pinholes 120).

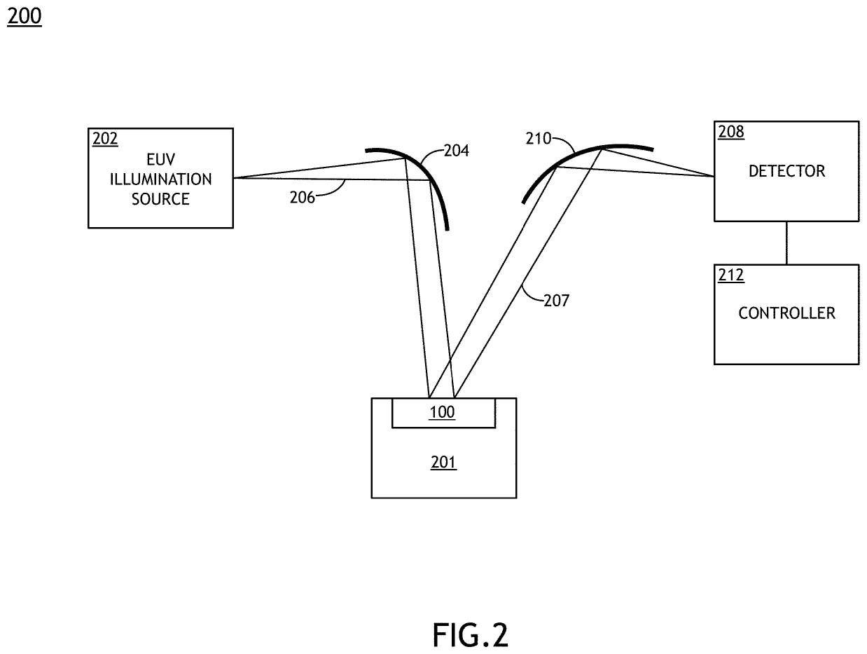

FIG. 2 illustrates an EUV mask inspection system 200 in accordance with one or more embodiments of the present disclosure. The EUV mask inspection system 200 may include an EUV illumination source 202, one or more illumination optics 204 for illuminating a test mask 201, one or more projection optics 210, one or more detectors 208, and one or more controllers 212.

The EUV illumination source 202 may include any illumination source known in the art to be suitable for the purposes contemplated by the present disclosure. For example, the EUV illumination source 202 may include a quasi-continuous wave laser. The EUV illumination source 202 may provide a high pulse repetition rate, low-noise, high power, stability, and reliability.

The EUV illumination source 202 may be configured to direct an EUV incident beam 206 onto a test mask 201 via the one or more illumination optics 204. For example, the EUV illumination source 202 may direct an EUV incident beam 206 onto the one or more illumination optics 204, and the one or more illumination optics 204 may be configured to focus the EUV incident beam 206 onto the test mask 201.

The illumination optics 204 may include any EUV-compatible optics known in the art suitable to precisely position the EUV incident beam 206 onto the test mask 201. For example, the illumination optics 204 may include one or more mirrors configured to reflect EUV radiation. The illumination optics 204 may be configured to direct the EUV incident beam 206 at the test mask 201 at any suitable angle, including, without limitation, normal or oblique angles.

Upon focusing on the test mask 201, the EUV incident beam 206 may be reflected and/or scattered as a reflected beam 207. The reflected beam 207 may be collected by one or more detectors 208 via one or more projection optics 210. For example, the one or more projection optics 210 may collect the reflected beam 207, and may focus the reflected beam 207 onto one or more portions of the one or more detectors 208. The one or more detectors 208 may include any detector known in the art to be suitable for the purposes contemplated by the present disclosure. For example, the one or more detectors 208 may include any CCD-type camera.

The one or more projection optics 210 may include any EUV-compatible optics known in the art suitable to project the reflected beam 207 onto the one or more detectors 208. For example, the one or more projection optics may include one or more mirrors configured to reflect EUV radiation.

The controller 212 may include one or more processors and memory. The one or more processors may be communicatively coupled to the one or more detectors 208. The one or more processors are configured to execute a set of program instructions maintained in memory, wherein the set of program instructions are configured to cause the one or more processors to execute one or more steps of the present disclosure. The components of the EUV mask inspection system 200 may be communicatively coupled via one or more wireline connections (e.g., copper wire, fiber optic cable, soldered connection, and the like), or a wireless connection (e.g., RF coupling, IR coupling, data network communication, and the like). The controller 212 may be communicatively coupled to a user interface.

Upon focusing the reflected beam 207 onto the one or more portions of the one or more detectors 208, the one or more controllers 212 may generate an image based on the reflected beam 207. For example, one or more processors of the one or more controllers 212 may analyze the intensity, phase, wave-front, and/or other characteristics of the reflected beam 207. The one or more processors may be configured to convert detected light of the reflected beam 207 into detected signals corresponding to one or more characteristics of the reflected beam 207. For example, the one or more processors may be configured to generate an image having different intensity values corresponding to different positions or portions of the test mask 201.

Based on the reflected beam 207, the one or more controllers 212 may be configured to measure one or more wave-front aberrations of the EUV mask inspection system 200. For example, the one or more controllers 212 may compare the one or more detected signals corresponding to one or more characteristics of the reflected beam 207 to an expected signal based on the particular test mask 201 in use. The expected signal based on a particular test mask 201 may be stored in a memory of the EUV mask inspection system 200, or may be provided via user input. Based on the one or more wave-front aberrations measured by the EUV mask inspection system 200, the one or more controllers 212 may determine one or more adjustments for adjusting one or more components of the EUV mask inspection system 200. For example, the one or more controllers 212 may determine one or more adjustments to the position of the one or more illumination optics 204 and/or the one or more projection optics 210.

The one or more processors of the one or more controllers 212 may be configured to execute program instructions maintained in memory. In this regard, the one or more processors of the one or more controllers 212 may execute any of the various process steps described throughout the present disclosure. The memory may store any type of data for use by any component of the EUV mask inspection system 200. For example, the memory may store wave-front aberration data generated by the EUV mask inspection system 200 or the like.

The one or more processors of the one or more controllers 212 may include any processing element known in the art. In this sense, the one or more processors may include any microprocessor-type device configured to execute algorithms and/or instructions. In one embodiment, the one or more processors may consist of a desktop computer, mainframe computer system, workstation, image computer, parallel processor, or any other computer system (e.g., networked computer) configured to execute a program configured to operate the EUV mask inspection system 200, as described throughout the present disclosure. It is noted that the term “processor” may be broadly defined to encompass any device having one or more processing elements, which execute program instructions from a non-transitory memory medium.

The memory may include any storage medium known in the art suitable for storing program instructions executable by the associated one or more processors of the one or more controllers 212. For example, the memory may include a non-transitory memory medium. By way of another example, the memory may include, but is not limited to, a read-only memory, a random-access memory, a magnetic or optical memory device (e.g., disk), a magnetic tape, a solid-state drive and the like. It is noted that memory may be housed in a common controller housing with the one or more processors. In one embodiment, the memory may be located remotely with respect to the physical location of the one or more processors of the one or more controllers 212. For instance, the one or more processors of the one or more controllers 212 may access a remote memory (e.g., server), accessible through a network (e.g., internet, intranet and the like). Therefore, the above description should not be interpreted as a limitation on the present invention but merely an illustration.

Additionally, the one or more controllers 212 and any associated components (e.g., the processors, the memory, or the like) may include one or more controllers housed in a common housing or within multiple housings. Further, the one or more controllers 212 may be integrated with and/or perform the functions of any components in the EUV mask inspection system 200.

The one or more controllers 212 may perform any number of processing or analysis steps disclosed herein including, but not limited to, receiving, generating, or applying a model to relate wave-front aberration data to selected attributes of sample features, which may involve a number of algorithms. For example, wave-front aberrations may be determined using any technique known in the art including, but not limited to, a geometric engine, a process modeling engine, or a combination thereof.

The one or more controllers 212 may further analyze collected data from the EUV mask inspection system 200 using any data fitting and optimization technique known in the art to apply the collected data to the model including, but not limited to libraries, fast-reduced-order models, regression, machine-learning algorithms such as neural networks, support-vector machines (SVM), dimensionality-reduction algorithms (e.g. principal component analysis (PCA), independent component analysis (ICA), local-linear embedding (LLE), and the like), sparse representation of data (e.g. Fourier or wavelet transforms, Kalman filters, algorithms to promote matching from same or different tool types, and the like).

In another embodiment, the one or more controllers 212 analyze raw data generated by the EUV mask inspection system 200 using algorithms that do not include modeling, optimization and/or fitting. It is noted herein that computational algorithms performed by the controller may be, but are not required to be, tailored for wave-front aberration metrology applications through the use of parallelization, distributed computation, load-balancing, multi-service support, design and implementation of computational hardware, or dynamic load optimization. Further, various implementations of algorithms may be, but are not required to be, performed by the one or more controllers 212 (e.g. though firmware, software, or field-programmable gate arrays (FPGAs), and the like).

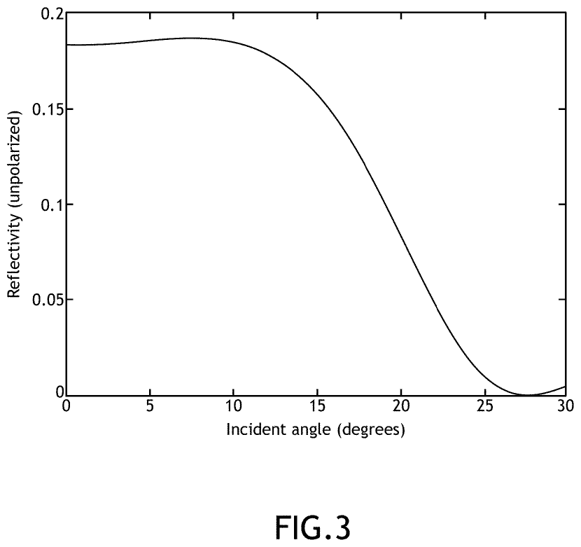

FIG. 3 is a plot illustrating the relationship between the reflectivity of unpolarized light of one or more portions of a pattern 100 and the angle of an EUV incident beam 206 of directed at the test mask 201, in accordance with one or more embodiments of the present disclosure. The EUV mask inspection system 200 may be configured such that the incident angle is between approximately 6 degrees and 17 degrees. It is noted that the reflectivity of the reflective portion 106 of the test mask 201 may result from one or more factors, including, without limitation, the composition of the reflective portion 106 (e.g., the materials used, the thickness and periodicity of the plurality of periodically repeating bilayers 116, the chief-ray angle, etc.).

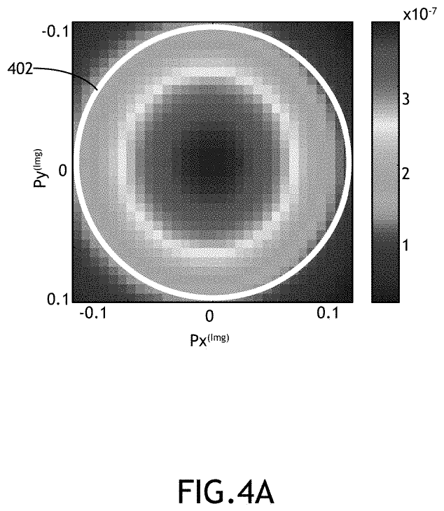

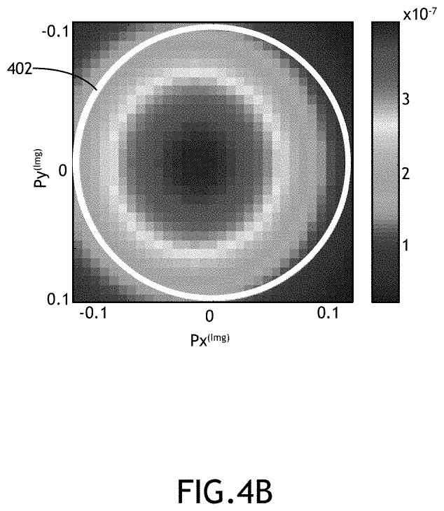

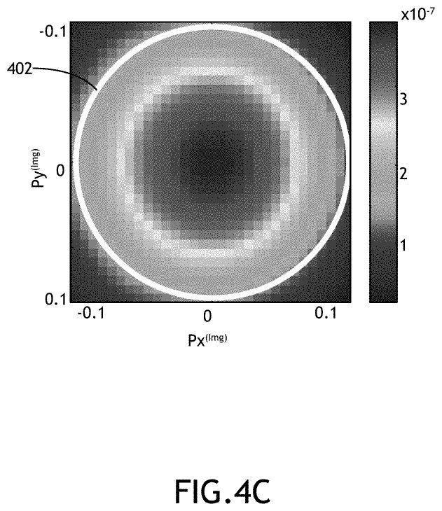

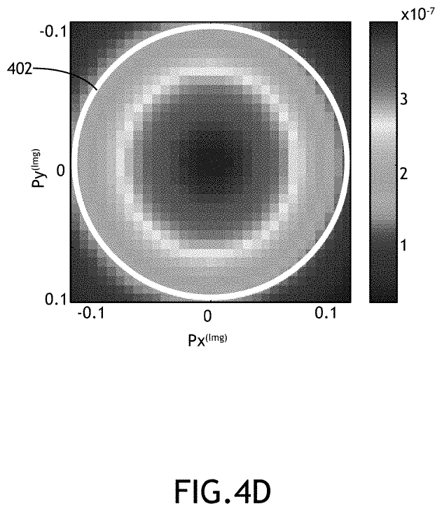

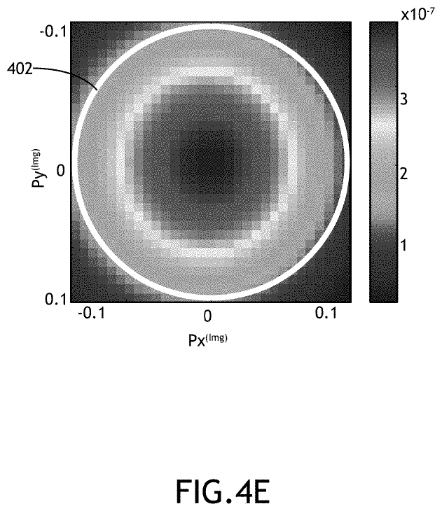

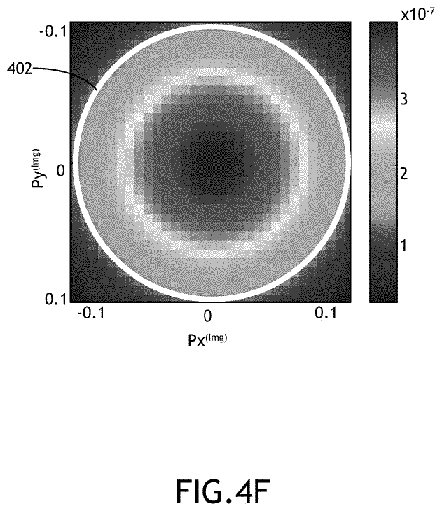

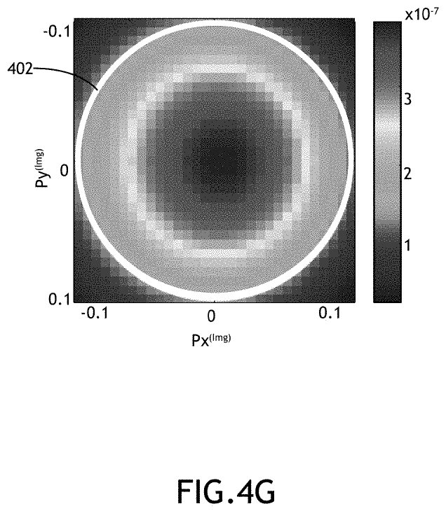

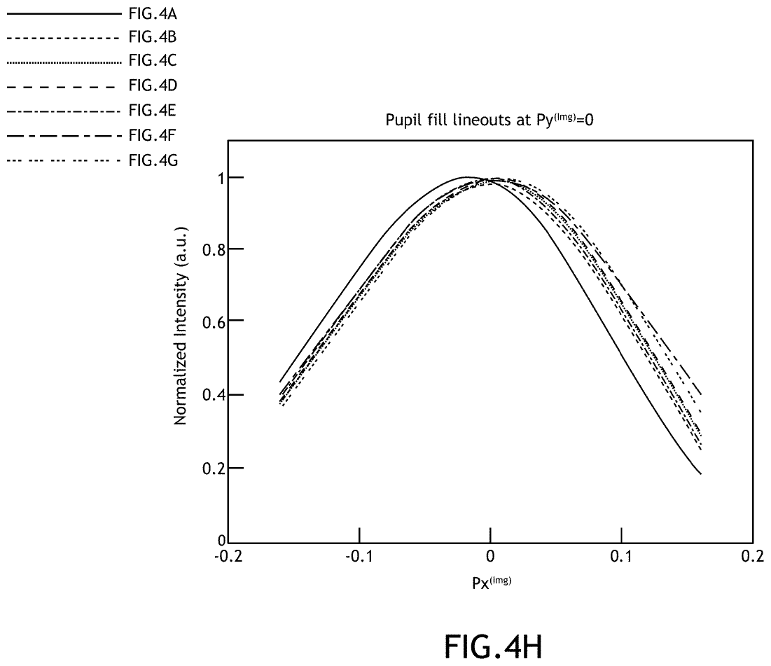

FIGS. 4A-4G are plots illustrating the intensity contrast of an imaging pupil 402 of the projection optics 210, in accordance with one or more embodiments of the present disclosure. It is noted that, while the plots of FIGS. 4A-4G illustrate representations of specific embodiments of the EUV mask inspection system 200, the EUV mask inspection system 200 is not limited to the embodiments disclosed therein. The plots of FIGS. 4A-4E illustrate the intensity contrast of the imaging pupil 402 of projection optics 210 of an EUV mask inspection system 200 having: eight periodically repeating bilayers 116 wherein the periodicity of the periodically repeating bilayers 166 was approximately 7.2 nm, one or more caps 128 formed substantially from ruthenium and having a thickness of approximately 2.5 nm, an illumination chief ray angle of 8.2 degrees, an illumination coherence parameter σ=0.7, and a numerical aperture equal to approximately 0.16.

FIG. 4A illustrates the intensity contrast of the fill of the imaging pupil 402 of the one or more projection optics 210 of an EUV mask inspection system 200 having a pattern 100 wherein the reflective portion 106 includes an array of multilayer pillars 114 having a plurality of periodically repeating bilayers 116. The one or more multilayer pillars 114 may include a protective layer of material deposited on the walls of the one or more multilayer pillars 114 and that is configured to prevent the oxidation of the one or more multilayer pillars 114.

FIG. 4B illustrates the intensity contrast of the fill of the imaging pupil 402 of the projection optics 210 of an EUV mask inspection system 200 having a pattern 100 wherein the absorption portion 104 includes an array of multilayer pillars 114 having a plurality of periodically repeating bilayers 116 disposed within an array of pinholes of the absorption portion 104. In a specific example, the array of pinholes in the absorption portion 104 may introduce undesirable reflective effects (e.g., shadowing) to the EUV mask inspection system 200, which undesirable reflective effects may decrease the uniformity of the fill of the imaging pupil 402.

FIG. 4C illustrates the intensity contrast of the fill of the imaging pupil 402 of the projection optics 210 of an EUV mask inspection system 200 having a pattern 100 wherein the reflective portion 106 includes a multilayer pillar 114 having a plurality of periodically repeating bilayers 116 and a cap 128. The pattern 100 also includes a plurality of absorbers 110 having an antireflective coating 112, where the multilayer pillar 114 is disposed within the plurality of absorbers 110.

FIG. 4D illustrates the intensity contrast of the fill of the imaging pupil 402 of the projection optics 210 of an EUV mask inspection system 200 having a pattern 100 wherein the reflective portion 106 includes a plurality of multilayer pillars 114 having a plurality of periodically repeating bilayers 116 and a cap 128. The pattern 100 also includes an absorber 110 having an antireflective coating 112, where the absorber 110 is disposed within the plurality of multilayer pillars 114.

FIG. 4E illustrates the intensity contrast of the fill of the imaging pupil 402 of the projection optics 210 of an EUV mask inspection system 200 having a pattern 100 wherein the reflective portion 106 includes a plurality of multilayer pillars 114 having a plurality of periodically repeating bilayers 116 and a cap 128. The absorption portion 104 includes a pinhole 120 disposed between the plurality of periodically repeating bilayers 116.

FIG. 4F illustrates the intensity contrast of the fill of the imaging pupil 402 of the projection optics 210 of an EUV mask inspection system 200 having a pattern 100 wherein the reflective portion 106 includes a plurality of pillars of reflective material 124. The absorption portion 106 includes pinhole 120 disposed between the plurality of pillars of reflective material 124.

FIG. 4G illustrates the intensity contrast of the fill of the imaging pupil 402 of the projection optics 210 of an EUV mask inspection system 200 having a pattern 100 wherein the reflective portion 106 includes a pillar of reflective material 124. The absorption portion 106 includes a plurality of pinholes 120 disposed between the plurality of pillars of reflective material 124.

FIG. 4H is a plot illustrating the various intensities on a coordinate plane of the fill of the imaging pupil 402 of the projection optics 210 of the EUV mask inspection system 200 having the patterns 100 corresponding to the test masks 201 described in FIGS. 4A-4G of the present disclosure, there the coordinate position along a y-axis of the imaging pupil is Py^{(Img)}=0.

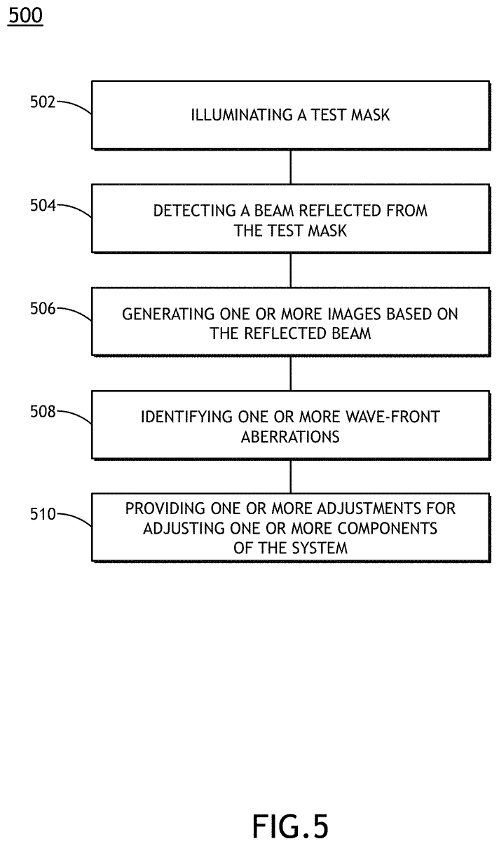

FIG. 5 is a process flow diagram illustrating sub-steps of a method 500 for using an EUV mask inspection system, in accordance with one or more embodiments of the present disclosure.

In one embodiment, the method 500 includes a step 502 of illuminating a test mask. For example, the illumination source 202 may direct an EUV incident beam 206 onto the test mask 201 via the one or more illumination optics 204.

In another embodiment, the method 500 includes a step 504 of detecting a beam reflected from the test mask 201. For example, the one or more detectors 208 may receive the reflected beam 207 from the test mask 201 via the one or more projection optics 204.

In another embodiment, the method 500 includes a step 506 of generating one or more images based on the reflected beam. For example, one or more processors of the one or more controllers 212 may analyze the intensity, phase or wave-front, and/or other characteristics of the reflected beam 207. The one or more processors may be configured to convert detected light of the reflected beam 207 into detected signals corresponding to one or more characteristics of the reflected beam 207. For example, the one or more processors may be configured to generate an image having different intensity values corresponding to different positions or portions of the test mask 201.

In another embodiment, the method 500 includes a step 508 of identifying one or more wave-front aberrations. For example, the one or more controllers 212 may compare the generated image based on the reflected beam 207 to an expected image based on the particular test mask 201 in use in order to identify one or more wave-front aberrations. The expected image based on a particular test mask 201 may be stored in the memory of the EUV mask inspection system 200, or may be provided via user input.

In another embodiment, the method 500 includes a step 510 of providing one or more adjustments for adjusting one or more components of the system. For example, the one or more controllers 212 may determine one or more adjustments to the position of the one or more illumination optics 204 and/or the one or more projection optics 210. The one or more adjustments for adjusting one or more components of the EUV mask inspection system 200 may be performed automatically by the EUV mask inspection system 200, or may be performed by a user, where the one or more controllers 212 may be configured to alert a user of the determination of such adjustments. The one or more adjustments for adjusting one or more components of the EUV mask inspection system 200 may compensate for one or more identified wave-front aberrations. For example, the one or more adjustments for adjusting one or more components of the EUV mask inspection system may reduce, or eliminate, the deviation from the desired wave-front caused by an aberration and/or may result in the mitigation of the effects of the one or more identified wave-front aberrations.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermediate components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A test mask for measuring wave-front aberration of an extreme ultraviolet (EUV) mask inspection system comprising:
a substrate formed from a material having substantially no reflectivity for EUV illumination;
one or more patterns formed on the substrate, wherein the one or more patterns comprise:
an absorption portion configured to absorb EUV illumination; and
a reflective portion configured to reflect EUV illumination, wherein the reflective portion and the absorption portion are positioned within a common plane on or above the substrate.

2. The test mask of claim 1, wherein the substrate is formed from silicon dioxide.

3. The test mask of claim 1, wherein the absorption portion comprises one or more absorbers.

4. The test mask of claim 3, further comprising:
an antireflective coating disposed on the one or more absorbers, wherein the antireflective coating is formed from a material having substantially no reflectivity for EUV illumination.

5. The test mask of claim 3, wherein the reflective portion comprises one or more multilayer pillars formed from a plurality of periodically repeating bilayers of molybdenum and silicon, where the thickness of each layer of the periodically repeating bilayers and the periodicity of the periodically repeating bilayers are configured for reflecting EUV illumination.

6. The test mask of claim 5, wherein the one or more multilayer pillars are of a thickness equivalent to a thickness of the one or more absorbers.

7. The test mask of claim 5, wherein the one or more multilayer pillars are embedded in the one or more absorbers.

8. The test mask of claim 4, wherein the reflective portion comprises a multilayer formed from a plurality of repeating bilayers of molybdenum and silicon.

9. The test mask of claim 8, wherein the absorption portion comprises a plurality of absorbers embedded in the multilayer formed from a plurality of repeating bilayers of molybdenum and silicon.

10. The test mask of claim 3, wherein the absorption portion comprises one or more pinholes in the reflective portion configured to expose one or more portions of the substrate.

11. The test mask of claim 10, wherein the reflective portion comprises a layer of reflective material.

12. The test mask of claim 11, wherein the reflective portion comprises at least one of palladium, platinum, or silver.

13. The test mask of claim 3, wherein the reflective portion comprises one or more pillars formed from a reflective material.

14. The test mask of claim 13, wherein the absorption portion comprises one or more pinholes configured to expose one or more portions of the substrate, where the one or more pinholes are disposed between the one or more pillars formed from a reflective material.

15. The test mask of claim 5, wherein the test mask further comprises one or more caps disposed on at least one of the absorption portion or the reflective portion, the one or more caps being formed from a material suitable to reduce oxidation of one or more portions of the test mask.

16. The test mask of claim 15, wherein the one or more caps are formed from ruthenium.

17. An extreme ultraviolet (EUV) mask inspection system, comprising:
an EUV illumination source;
one or more EUV illumination optics configured to direct an EUV beam from the EUV illumination source onto a test mask, the test mask comprising a substrate formed from a material having substantially no reflectivity for EUV illumination, one or more patterns formed on the substrate, wherein the one or more patterns comprise an absorption portion configured to absorb EUV illumination and a reflective portion configured to reflect EUV illumination, wherein the absorption portion and the reflective portion are positioned within a common plane on or above the substrate, and one or more caps disposed on at least one of the absorption portion or the reflective portion, the one or more caps being formed from a material suitable to reduce oxidation of one or more portions of the test mask;
one or more detectors;
one or more EUV projection optics configured to collect EUV illumination reflected from the test mask and direct the EUV illumination onto the one or more detectors; and
one or more controllers, wherein the one or more controllers includes one or more processors communicatively coupled to the one or more detectors, wherein the one or more processors are configured to execute a set of program instructions maintained in memory, wherein the set of program instructions are configured to cause the one or more processors to:
receive one or more signals from the one or more detectors indicative of the EUV illumination reflected from the test mask; and
identify one or more wave-front aberrations across the EUV beam based on the one or more signals from the one or more detectors indicative of the EUV illumination reflected from the test mask.

18. The system of claim 17, wherein the substrate is formed from silicon dioxide.

19. The system of claim 17, wherein the absorption portion and the reflective portion are disposed on the substrate.

20. The system of claim 19, wherein the absorption portion comprises one or more absorbers coated with a material having substantially no reflectivity for EUV illumination.

21. The system of claim 19, wherein the reflective portion comprises one or more multilayer pillars formed from a plurality of periodically repeating bilayers of molybdenum and silicon, where the thickness of each layer of the periodically repeating bilayers and the periodicity of the periodically repeating bilayers are configured for reflecting EUV illumination.

22. The system of claim 21, wherein the one or more multilayer pillars are of a thickness equivalent to the thickness of the one or more absorbers.

23. The system of claim 21, wherein the one or more multilayer pillars are embedded in the one or more absorbers.

24. The system of claim 20, wherein the reflective portion comprises a multilayer formed from a plurality of repeating bilayers of molybdenum and silicon.

25. The system of claim 24, wherein the absorption portion comprises a plurality of absorbers embedded in the multilayer formed from a plurality of repeating bilayers of molybdenum and silicon.

26. The system of claim 19, wherein the absorption portion comprises one or more pinholes in the reflective portion configured to expose one or more portions of the substrate.

27. The system of claim 26, wherein the reflective portion comprises a layer of reflective material.

28. The system of claim 27, wherein the reflective material comprises at least one of palladium, platinum, or silver.

29. The system of claim 19, wherein the reflective portion comprises one or more pillars formed from a reflective material.

30. The system of claim 29, wherein the absorption portion comprises one or more pinholes configured to expose one or more portions of the substrate, where the one or more pinholes are disposed between the one or more pillars formed from a reflective material.

31. The system of claim 17, wherein the one or more processors are configured to provide one or more adjustments for adjusting at least one of the EUV illumination source, one or more EUV illumination optics, or the one or more EUV projection optics to compensate for the one or more identified wave-front aberrations in the EUV beam.

32. A method of using an extreme ultraviolet (EUV) mask inspection system, comprising:
illuminating a test mask comprising a substrate formed from a material having substantially no reflectivity for EUV illumination, one or more patterns formed on the substrate, wherein the one or more patterns comprise an absorption portion configured to absorb EUV illumination and a reflective portion configured to reflect EUV illumination, wherein the absorption portion and the reflective portion are positioned within a common plane on or above the substrate, and one or more caps disposed on at least one of the absorption portion or the reflective portion, the one or more caps being formed from a material suitable to reduce oxidation of one or more portions of the test mask;
detecting a reflected beam;
generating one or more images based on the reflected beam;
identifying one or more wave-front aberrations across the one or more images; and
providing one or more adjustments for adjusting one or more components of the EUV inspection system.

33. The method of claim 32, wherein the substrate is formed from silicon dioxide.

34. The method of claim 32, wherein the absorption portion and the reflective portion are disposed on the substrate.

35. The method of claim 34, wherein the absorption portion comprises one or more absorbers coated with a material having substantially no reflectivity for EUV illumination.

36. The method of claim 34, wherein the reflective portion comprises one or more multilayer pillars formed from a plurality of periodically repeating bilayers of molybdenum and silicon, where the thickness of each layer of the periodically repeating bilayers and the periodicity of the periodically repeating bilayers are configured for reflecting EUV illumination.

37. The method of claim 36, wherein the one or more multilayer pillars are of a thickness equivalent to the thickness of the one or more absorbers.

38. The method of claim 36, wherein the one or more multilayer pillars are embedded in the one or more absorbers.

39. The method of claim 35, wherein the reflective portion comprises a multilayer formed from a plurality of repeating bilayers of molybdenum and silicon.

40. The method of claim 39, wherein the absorption portion comprises a plurality of absorbers embedded in the multilayer formed from a plurality of repeating bilayers of molybdenum and silicon.

41. The method of claim 34, wherein the absorption portion comprises one or more pinholes in the reflective portion configured to expose one or more portions of the substrate.

42. The method of claim 41, wherein the reflective portion comprises a layer of reflective material.

43. The method of claim 42, wherein the reflective portion comprises at least one of palladium, platinum, or silver.

44. The method of claim 34, wherein the reflective portion comprises one or more pillars formed from a reflective material.

45. The method of claim 44, wherein the absorption portion comprises one or more pinholes configured to expose one or more portions of the substrate, where the one or more pinholes are disposed between the one or more pillars formed from a reflective material.

46. The method of claim 32, wherein the illuminating a test mask comprises directing an EUV incident beam onto the test mask.
